(19) United States
(12) Patent Application Publication
(10) Pub. No.: US 2025/0062239 A1
(43) Pub. Date: Feb. 20, 2025

(54) SIGNAL CHANNEL, MODULE SUBSTRATE, AND SEMICONDUCTOR SYSTEM INCLUDING THE SAME

(71) Applicant: SAMSUNG ELECTRONICS CO., LTD., Suwon-si (KR)

(72) Inventors: HYUN JUN PARK, Suwon-si (KR); Woo-Seok Choi, Suwon-si (KR)

(73) Assignee: UIF (University Industry Foundation), Yonsei University, Seoul (KR)

(21) Appl. No.: 18/590,686

(22) Filed: Feb. 28, 2024

(30) Foreign Application Priority Data
Sep. 20, 2023 (KR) 10-2023-0125791

(51) Int. Cl. H01L 23/538; H01L 23/00; H01L 25/18; H10B 80/00

(52) U.S. Cl. CPC H01L 23/5386; H01L 25/18; H10B 80/00; H01L 24/16; H01L 24/17; H01L 2224/16146; H01L 2224/16225; H01L 2224/17181; H01L 2924/1436

(57) ABSTRACT

A signal channel according to embodiments of the present disclosure includes a plurality of signal lines disposed on a plurality of layers spaced apart from each other in a first direction and connecting first points and second points to each other. A plurality of sections are defined between the first points and the second points. A first signal line disposed on a first layer of the plurality of layers in a first section of the plurality of sections is electrically connected to a second signal line disposed on a second layer of the plurality of layers in a second section of the plurality of sections.

### CROSS-REFERENCE TO RELATED APPLICATION

This application claims priority under 35 U.S.C § 119 to Korean Patent Application No. 10-2023-0125791, filed in the Korean Intellectual Property Office on Sep. 20, 2023, the entire contents of which are herein incorporated by reference.

### TECHNICAL FIELD

The present disclosure relates to semiconductors and, more specifically, to a signal channel, a module substrate including the same, and a semiconductor system including the same.

### DISCUSSION OF THE RELATED ART

When signal lines on multiple layers of a module substrate are used as signal channels to increase throughput, the signal channels may have different characteristics from each other due to differences in the specifications of the various signal lines. Different characteristics between signal channels included in the same channel group may result in differences in the single bit response characteristic and crosstalk response characteristic of the signal channels.

### SUMMARY

A signal channel according to embodiments of the present disclosure to solve such a technical object includes a plurality of signal lines disposed on a plurality of layers spaced apart from each other in a first direction and connecting first points and second points, where a plurality of sections are provided between the first points and the second points, and where a first signal line disposed on a first layer of the plurality of layers in a first section of the plurality of sections is electrically connected to a second signal line disposed on a second layer of the plurality of layers in a second section of the plurality of sections.

A module substrate according to embodiments of the present disclosure includes: a substrate main body including a dielectric material and including a plurality of layers spaced apart from each other in a first direction; and a plurality of signal lines that are disposed on the plurality of layers, connect first points and second points, and have a cyclic structure, wherein a plurality of sections are provided between the first points and the second points, and a first signal line disposed on a first layer of the plurality of layers in a first section of the plurality of sections is electrically connected to a second signal line disposed on a second layer of the plurality of layers in the second section of the plurality of sections.

A semiconductor system according to embodiments of the present disclosure includes: a plurality of stacked memory dies; a buffer die below the plurality of memory dies; a memory controller; and an interposer that includes a plurality of signal lines connecting first points of the memory controller and second points of the buffer die, wherein a plurality of sections are provided between the first points and the second points, and a first signal line disposed on a first layer of the plurality of layers in a first section of the plurality of sections is electrically connected to a second signal line disposed on a second layer of the plurality of layers in a second section of the plurality of sections.

### BRIEF DESCRIPTION OF THE DRAWINGS

FIG. 1 is a block diagram illustrating a semiconductor system according to embodiments of the present disclosure.

FIG. 2 is a cross-sectional view of a semiconductor system according to embodiments of the present disclosure.

FIG. 3 is a schematic view of signal channels.

FIG. 4 is a cross-sectional view of the signal channels of FIG. 3.

FIG. 5 is a schematic view of signal channels according to embodiments of the present disclosure.

FIGS. 6A, 6B, and 6C are cross-sectional views of signal channels according to embodiments of the present disclosure.

FIG. 7 is a schematic view of signal channels.

FIG. 8 is a cross-sectional view of the signal channels of FIG. 7.

FIG. 9 and FIG. 10 are graphs illustrating signals measured through the signal channels of FIG. 7.

FIG. 11 is a schematic view of signal channels according to embodiments of the present disclosure.

FIG. 12 is a table representing signal lines allocated to signal channels according to embodiments of the present disclosure.

FIGS. 13A and 13B show signal lines allocated to signal channels according to embodiments of the present disclosure.

FIGS. 14A, 14B, 14C, and 14D are cross-sectional views of signal channels according to embodiments of the present disclosure.

FIG. 15 illustrates a connection method of signal lines according to embodiments of the present disclosure.

FIG. 16 and FIG. 17 are graphs illustrating signals measured through the signal channels of FIG. 12.

FIGS. 18A and 18B are heat maps illustrating the similarity of the signal channel response according to embodiments of the present disclosure.

### DETAILED DESCRIPTION OF THE EMBODIMENTS

In the following detailed description, certain embodiments of the present invention have been shown and described. As those skilled in the art would realize, the described embodiments may be modified in various different ways, all without departing from the spirit or scope of the present disclosure.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. Like reference numerals may designate like elements throughout the specification and the drawings. In the flowchart described with reference to the drawing, the order of operations may be changed, several operations may be merged, some operations may be divided, and specific operations might not be performed.

In the present specification, expressions described in the singular may be construed in the singular or plural unless an explicit expression such as “one” or “single” is used. In the present specification, the terms including ordinal numbers such as first, second, etc. may be used to describe various elements, but the elements are not necessarily limited by the terms. The terms are used for the purpose of distinguishing one element from another element.

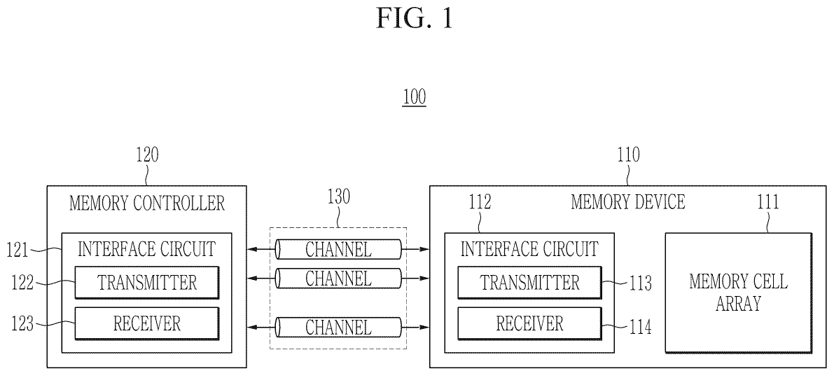

FIG. 1 is an exemplary block diagram of a semiconductor system according to embodiments of the present disclosure.

Referring to FIG. 1, a semiconductor system 100 includes a memory device 110 and a memory controller 120.

The memory device 110 and the memory controller 120 are electrically connected through a memory interface and thus may exchange a signal through the memory interface. In embodiments of the present disclosure, the memory device 110 and the memory controller 120 may transmit and receive DQ signals to each other using a serial interfacing method. The memory controller 120 may access the memory device 110 according to a request from an external host to the semiconductor system 100. The memory controller 120 may communicate with the host through various protocols. For example, the memory controller 120 may communicate with the external host through in-parallel interfacing. In embodiments of the present disclosure, the memory controller 120 may communicate with the host through serial interfacing.

The memory device 110 includes a memory cell array 111 and an interface circuit 112. The memory cell array 111 includes a plurality of memory cells electrically connected to a plurality of rows and a plurality of columns. The interface circuit 112 may receive a signal transmitted from beyond the memory device 110 (i.e., a memory controller 120 and the like), or may output a signal from the memory device 110 externally. For example, the interface circuit 112 may receive data transmitted from the memory controller 120, and may store the data in the memory cell array 111 or output data stored in the memory cell array 111 to the memory controller 120. The interface circuit 112 may include a transmitter 113 and a receiver 114.

The transmitter 113 may output a signal generated by the memory device 110. The transmitter 113 may generate a multi-level signal based on a logic state including a plurality of bits. For example, the transmitter 113 may use PAM4 signaling methods (or other types of multi-level signaling methods) to generate a signal with an amplitude corresponding to the logic state. The transmitter 113 may receive data using a single input line. In embodiments of the present disclosure, the transmitter 113 may generate a binary-level signal (e.g., NRZ signal). The transmitter 113 may use single-ended signaling to generate a multi-level signal. The transmitter 113 may receive data from the memory cell array 111 and output a data input-output signal based on the data. The transmitter 113 may output a signal in parallel through signal channels 130. When the transmitter 113 outputs a signal in parallel to the signal channels 130, a transition due to the signal may occur in the signal channels 130. For example, when a transition occurs in a channel adjacent to the target channel, signal transmission of the target channel may be interrupted. Such a phenomenon may be referred to as crosstalk. The transmitter 113 of the memory device 110 subsequently equivalent to a transmitter 122 of the memory controller 120, and therefore, a description of the transmitter 122 of the memory controller 120 refers to the above description.

The signal channels 130 may be a path through which the memory device 110 and the memory controller 120 are physically or electrically connected. For example, the signal channels 130 may be implemented using a through silicon via (TSV), a trace, or a coaxial cable. In embodiments of the present disclosure, each of the signal channels 130 may be a trace disposed in an interposer disposed between the memory cell array 111 and the memory controller 120. As the number of the signal channels 130 increases, the amount of data (i.e., data throughput) transmitted to the memory device 110 may be increased without increasing the data transmission speed. To increase the number of signal channels 130, signal lines disposed on several layers within the interposer may be used as the signal channels 130. In embodiments of the present disclosure, each of the signal channels 130 may include signal lines on several layers in the interposer. A length of each signal line on the layers included in each of the signal channels 130 may be substantially equivalent. For example, one of the signal channels 130 may include a first signal line on a first layer and a second signal line on a second layer, that is different from the first layer, in the interposer. In this case, a length of the first signal line and a length of the second signal line may be substantially equivalent. Each of the signal channels 130 may be referred to as a wide system interface. In embodiments of the present disclosure, one or more of the signal channels 130 may have one-way, or one or more of the signal channels 130 may be two-way.

The receiver 114 may determine a symbolically expressed logic state of a multi-level signal received using the signal channels 130. In some cases, the receiver 114 may determine an amplitude of the received multi-level signal. Based on the determined amplitude, the receiver 114 may determine a logic state expressed by the multi-level signal. The receiver 114 may output data using a signal output line. In embodiments of the present disclosure, the receiver 114 may decode a binary-level signal (e.g., NRZ signal). For example, the receiver 114 may receive a DQ signal provided from the memory controller 120 and generate data by decoding the received DQ. The receiver 114 may output the generated data to the memory cell array 111. Since the receiver of the memory device 110 is substantially equivalent to the receiver 123 of the memory controller 120, a description of the receiver 123 of the memory controller 120 will refer to the above description.

The memory controller 120 may control a memory operation of the memory device 110 by providing a control signal to the memory device 110. The control signal may include a command and an address. In some embodiment, the memory controller 120 may control the memory operation such as access to the memory cell array 111, reading, or writing by providing the command and the address to the memory device 110. According to a read operation, data may be transmitted as a DQ signal from the memory cell array 111 to the memory controller 120, and according to a write operation, data may be transmitted as a DQ signal from the memory controller 120 to the memory cell array 111.

The command may include an activate command, a read/write command, and a refresh command. The activation command may be a commend for changing a target row of the memory cell array 111 to an active state to write data to or read data from the memory cell array 111. In response to the activation command, the memory cell of the target row may be activated (e.g., driven). The read/write command may be a command for operating reading or writing operation in a target memory cell of the row changed to the active state. The refresh command may be a command for performing a refresh operation in the memory cell array 111.

The interface circuit 121 of the memory controller 120 may output the data as a DQ to the memory device 110 or output a DQ output from the memory device 110. The interface circuit 121 may include a transmitter 122 and a receiver 123.

The memory device 110 may be a storage device based on a semiconductor device. In embodiments of the present disclosure, the memory device 110 may include a dynamic random access memory (DRAM). In embodiments of the present disclosure, the memory device 110 may include other volatile or non-volatile memory device in which the transmitter 113 or receiver 11 is used.

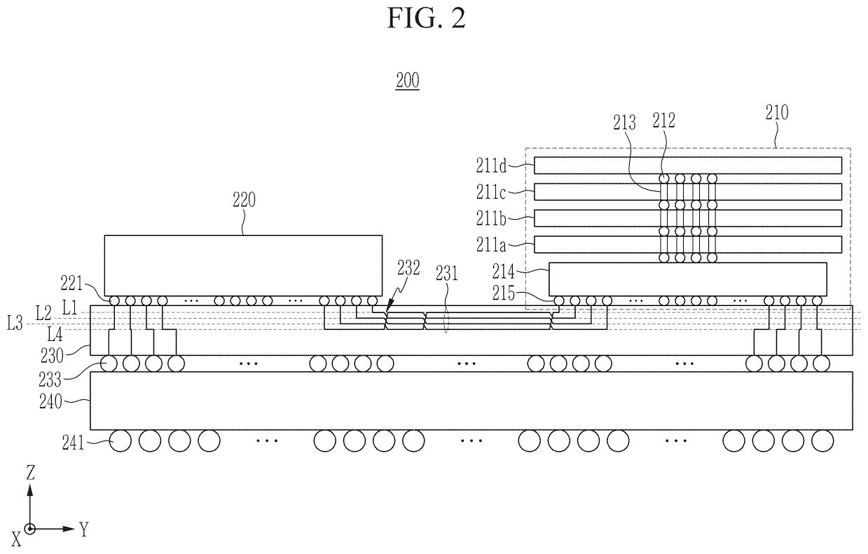

Hereinafter, referring to FIG. 2, a structure of the semiconductor system 100 will be described.

FIG. 2 is a schematic view of a semiconductor system according to embodiments of the present disclosure.

Referring to FIG. 2, a semiconductor system 200 include a memory controller 220 and a memory device 210. The semiconductor system 200 may further include an interposer 230 that connects the memory controller 220 and the memory device 210. The memory device 210 and the memory controller 220 may be disposed on the interposer 230. The memory controller 220 and the memory device 210 may be placed on the same plane (e.g., their respective lower surfaces and/or their respective upper surfaces may align in the horizontal direction). A structure of such a semiconductor system 200 may be referred to as a 2.5-dimensional (D) package structure. The semiconductor system 200 may further include a package substrate 230 where the interposer 230 is disposed.

The memory device 210 may be a high-bandwidth memory (HBM) device. The memory device 210 may provide more bandwidth for data transmission per electric power unit used in the memory device 210. The memory device 210 may be a DRAM device.

The memory device 210 may include a buffer die (or base die) 214 and at least one of core dies (or memory die, deck) 211a to 211d disposed on the buffer die 214. Transmission of signals between the buffer die 214 and the core dies 211a to 211d may be performed through various through silicon vias (TSVs) 213. For example, first bumps 212 may be respectively formed between the stacked core dies 211a to 211d and between the core die 211a and the buffer die 214, and the TSVs 213 that penetrate the core dies 211a to 211d may be formed between the first bumps 212.

Second bumps 215 may be disposed between the memory device 210 and the interposer 230. In embodiments of the present disclosure, the buffer die 214 and the interposer 230 may be combined using micro pillars 215.

The buffer die 214 may include a plurality of buffers electrically connected to signal lines 231. The plurality of buffers may output signals output to the signal channels through the signal lines 231.

Third bumps 221 may be disposed between the memory controller 220 and the interposer 230. The first bump 212, the second bump 215, and the third bump 221 may be micro bumps. The memory controller 220 may output signals to the memory device 210 through the signal lines 231. For example, the memory controller 220 may transmit a command signal and an address signal to the memory device 210 through the signal lines 231, and may exchange a DQ signal with the memory device 210. The memory controller 220 may be included in a graphic processing unit (GPU) die, a central processing unit (CPU) die, or a system on chip (SoC) die. The interposer 230 may include a plurality of layers L1 to L4 and the signal lines 231 disposed on the plurality of layers L1 to L4. Fourth bumps 233 may be disposed on a lower surface of the interposer 230, for example, between the interposer 230 and the package substrate 240.

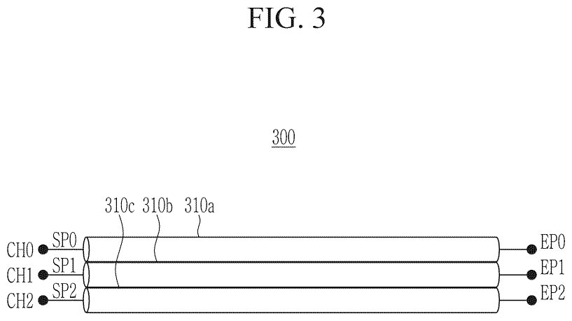

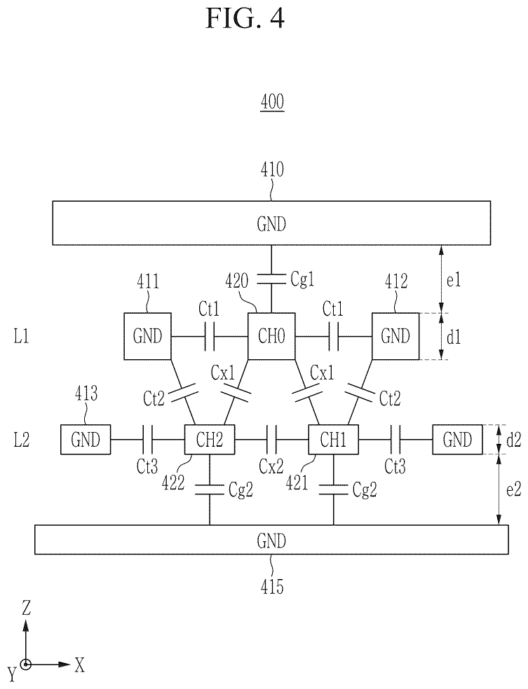

The signal lines 231 each may be used as a signal channel. The signal channels may form one signal channel group. One signal channel group may be formed by signal lines 231 adjacent to each other. The signal lines 231 adjacent to each other may be disposed on multiple layers L1 to L4. For example, eight data signal channels outputting an 8-bit data signal may form one signal channel group, and each data signal channel may be formed by signal lines on different layers L1 to L4. However, there may be differences in specifications (e.g., differences in the physical arrangement and/or disposition) between the various signal lines 231 on the multiple layers L1 to L4. Therefore, the signal transmission characteristic between signal channels is different due to the difference in the specifications of the signal lines 231. Different characteristics between signal channels included in the same signal channel group result in differences in the single bit response characteristic and crosstalk response characteristic of the signal channels. For example, due to a specification difference between a signal line disposed on the layer L1 and transmitting a DQ0 signal and a signal line disposed on the layer L3 and transmitting a DQ1 signal, the response characteristic between the DQ0 signal and the DQ1 signal may occur. The signal channels and the signal lines, according to embodiments of the present disclosure, will be described with reference to FIG. 3 and FIG. 4.

FIG. 3 is a schematic view of signal channels, and FIG. 4 is a cross-sectional view of the signal channels of FIG. 3.

Referring to FIG. 3, a signal channel group may include three signal channels CH0, CH1, and CH2. The signal channels CH0, CH1, and CH2 are single-ended channels, and they may electrically connect first points SP0, SP1, and SP2 and second points EP0, EP1, and EP2 to one another. One signal channel (CH0, CH1, or CH2) may be implemented by one signal line (310a, 310b, or 310c), respectively. In FIG. 3, it is assumed that signal lines 310a, 310b, and 310c have certain specifications between the first points SP0, SP1, and SP2 and the second points EP0, EP1, and EP2. The signal lines 310a, 310b, and 310c may have different specifications. Therefore, differences in response characteristics may occur between signals transmitted through the signal channels CH0, CH1, and CH2.

Referring to FIG. 4 together, signal lines 420, 421, and 422 that transmit a signal may be disposed on multiple layers L1 and L2 in the interposer 400. For example, the signal line 420 corresponding to the channel CH0 may be disposed on the layer L1, and the signal lines 421 and 422 corresponding to the channels CH1 and CH2 may be disposed on the layer L2. Reference lines 411, 412, 413, and 414, to which a reference voltage is applied, may be disposed the multiple layers L1 and L2 within the interposer 400. The signal lines 420, 421, and 422 and the reference lines 411, 412, 413, and 414 may extend along the Y-axis direction. The reference lines 411, 412, 413, and 414 may be disposed around the signal lines 421, 422, and 423 that form one signal channel group. For example, on the same layer L1, the reference lines 411 and 412 may be disposed around the signal line 420 in the X-axis direction. For example, on the same layer L1, the signal line 420 may be disposed between the reference lines 411 and 412. On the same layer L2, the reference lines 413 and 414 may be disposed around the signal lines 421 and 422 in the X-axis direction. For example, on the same layer L2, the signal lines 421 and 422 may be disposed between the reference lines 413 and 414. A reference voltage applied to the reference lines 411, 412, 413, and 414 may be a ground voltage GND.

The interposer 400 may further include a first reference plate 410 to which the reference voltage is applied above the layers L1 and L2 and a second reference voltage 415 to which the reference voltage is applied below the layers L1 and L2. The first reference plate 410 and the second reference plate 415 are formed of a metal to which the reference voltage is applied, and a space between the first reference plate 410 and the second reference plate 415 may be filled with one or more dielectrics. The reference voltage applied to the first reference plate 410 and the second reference plate 415 may be a ground voltage GND. In embodiments of the present disclosure, the interposer 400 might not include the first reference plate 410 and the second reference plate 415, or may include only one of the first reference plate 410 and the second reference plate 415.

The signal line 420 may form capacitive couplings Cg1, Ct1, and Cx1 with the first reference plate 410, the reference lines 411 and 412, and the signal lines 421 and 422, respectively. The signal line 421 may form capacitive bonds Cg2, Ct2, Ct3, Cx1, Cx2 with the second reference plate 415, reference lines 412, 414, and signal lines 420, and 422, respectively. The signal line 422 may form capacitive couplings Cg2, Ct2, Ct3, Cx1, and Cx2 with the second reference plate 415, the reference lines 411, 413, and the signal lines 420, 421, respectively. A thickness d1 of the signal line 420 and the reference lines 411 and 412 in the Z-axis direction on the layer L1 and a thickness d2 of the signal lines 421 and 422 and the reference lines 413 and 414 in the Z-axis direction on the layer L2 may be different from each other. Widths of the reference lines 412 and 414 and the signal lines 420 and 422 in the X-axis direction may be different from each other. A distance e1 between the signal line 420 and the first reference plate 410 and a distance e2 between the signal lines 421 and 422 and the second reference plate 415 may be different from each other. For example, since the signal lines 420, 421, and 422 have different thicknesses and/or widths, resistivities of the signal lines 420, 421, and 422 may be different from each other. In addition, the signal line 420 and the signal line 422 may have different capacitance values depending on the capacitive coupling formed with adjacent reference lines and reference plates. Due to differences in the specifications of the signal lines 420, 421, and 422, differences in response characteristics may occur between signals transmitted through the signal channels CH0, CH1, and CH2.

In embodiments of the present disclosure, the three signal channels CH0, CH1, and CH2, within the signal channel group, may be implemented by signal lines having a cyclic structure. As used herein, the phrase “cyclic structure” may mean that the signal lines are twisted and/or braided with one another so that they exhibit a repeating arrangement in which they take turns occupying relative positions. Signal lines having a cyclic structure within a signal channel group may include signal lines included in a closed plane with the largest area among closed planes formed by three or more signal lines among the signal lines of the signal channel group. For example, with three signal lines 420, 421, and 422 on the XZ plane as points on the plane, one closed plane may be formed by virtual straight lines including two of the three points. Since the closed plane has the largest area, the three signal lines 420, 421, and 422 included in the closed plane may have a cyclic structure. A closed plane may be a closed figure made up of virtual straight lines. Since a closed plane is formed by virtual straight lines connecting specific points of the signal line on the XZ plane, if one signal channel group includes four or more signal lines, and three of the four or more signal lines are not located in one virtual straight line, multiple closed planes can be formed.

In an embodiment, one signal channel implemented with signal lines having a cyclic structure, among signal channels, may include signal lines 231 on multiple layers L1 to L4. For example, the signal channel may include a signal line disposed on the layer L1, a signal line disposed on the layer L2, a signal line disposed on the layer L3, and a signal line disposed on the layer L4. For example, each of the signal lines 231 may be electrically connected to each of other signal lines 231 at a plurality of connection points 232. In addition, at least one of the signal lines 231 may be electrically connected to one of the signal lines 231 disposed on a different layer in the plurality of connection portions 232. For example, in the connection portion 232, among the signal lines 231, a signal line disposed on the layer L1 may be electrically connected to a signal line disposed on the layer L2, a signal line disposed on the layer L2 may be electrically connected to a signal line disposed on the layer L3, and a signal line disposed on the layer L3 may be electrically connected to a signal line disposed on the layer L4, and a signal line disposed on the layer L4 may be electrically connected to a signal line disposed on the layer L1. For example, the position of the signal line corresponding to each signal channel in the connection portion 232 may be changed. Although it has been described above that the signal lines 231 disposed on the four layers L1 to L4 in the connection portion 232 are respectively electrically connected to different signal lines, some signal lines might not be electrically connected to different signal lines. In some embodiment, signal lines included in one signal channel may have substantially the same length. Since each signal channel contains at least one signal line with a different specification, substantially equivalent response characteristics of signals transmitted through the signal channels may be obtained. For example, when all signal channels implemented with signal lines with a cyclic structure within one signal channel group each includes all signal lines on which all signal channels can be placed with equal length, differences in response characteristics that may occur due to differences in signal line specifications between one signal channel and another signal channel can be minimized.

The package substrate 240 may be combined with other components using one or more solder balls 241.

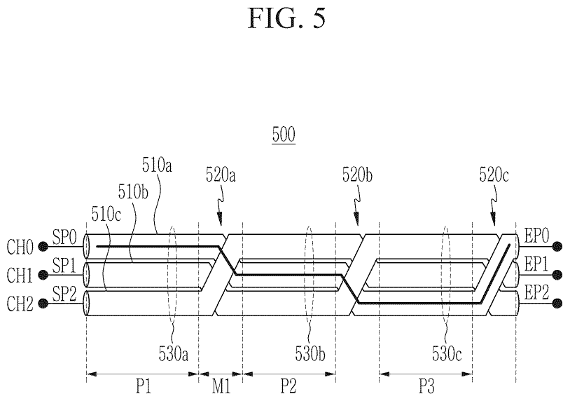

FIG. 5 is a schematic view of signal channels according to embodiments of the present disclosure.

Referring to FIG. 5, a signal channel group may include three signal channels CH0, CH1, and CH2 implemented with signal lines having a cyclic structure. The signal channels CH0, CH1, and CH2 may be single-ended channels, and may electrically connect first points SP0, SP1, and SP2 and second points EP0, EP1, and EP2. In FIG. 5, it is assumed that signal lines 510a, 510b, and 510c have certain specifications between the first points SP0, SP1, and SP2 and the second points EP0, EP1, and EP2. The signal lines 510a, 510b, and 510c may have different specifications. A plurality of sections 530a, 530b, and 530c may be provided between the first points SP0, SP1, and SP2 and the second points EP0, EP1, and EP2. In embodiments of the present disclosure, the number of the plurality of sections 530a, 530b, and 530c may be an integer times the number of signal lines 510a, 510b, and 510c having a cyclic structure.

One signal channel CH0, CH1, or CH2 may be implemented with several signal lines 510a, 510b, and 510c. For example, a signal channel CH0 connecting the first point SP0 and the second point EP0 may include a first signal line 510 electrically connected to the first point SP0 in the first section 530a, and a second signal line 520b in the second section 530b, and a third signal line 510c in the third section 530c. The third signal line 510c of the third section 530c may be electrically connected back to the second point EP0. A length P1 of the first section 530a, a length P2 of the second section 530b, and a length P3 of the third section 530c may be substantially equivalent. For example, the length of each of the three signal lines included in the first signal channel CH0 may be substantially equivalent to each other. Connection portions 520a, 520b, and 520c may be positioned in response to the sections 530a, 530b, and 530c, respectively. In each of the connection portions 520a, 520b, and 520c, each of the signal line 510a, 510b, and 510c may be electrically connected to different signal lines 510a, 510b, and 510c. For example, in the connection portion 520a, the first signal line 510a may be electrically connected to the second signal line 510b, the second signal line 510b may be electrically connected to the third signal line 510c, and the third signal line 510c may be electrically connected to the first signal line 510a. A length M1 of each of the connection portions 520a, 520b, and 520c may be shorter than lengths P1, P2, and P3 of the respective sections 530a, 530b, and 530c.

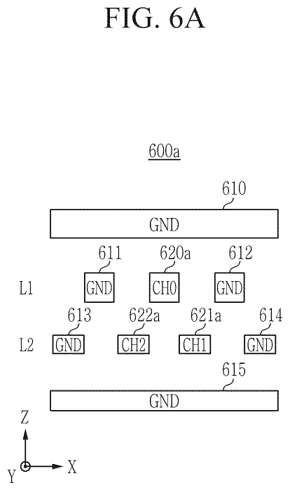

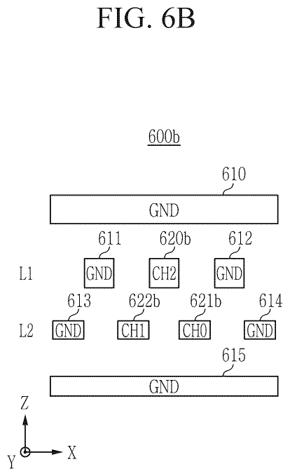

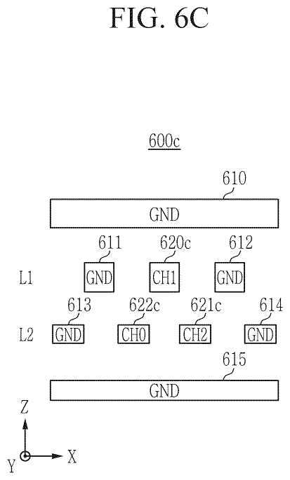

Each of the signal channels CH0, CH1, and CH2 implemented with signal lines having a cyclic structure includes at least one of the signal lines 510a, 510b, and 510c having different specifications, and therefore it is possible to obtain substantially equivalent response characteristics of signals transmitted through signal channels CH0, CH1, and CH2. When the signal channels CH0, CH1, and CH2 implemented with signal lines having a cyclic structure and included in one signal channel group each includes signal lines 510a, 510b, and 510c corresponding to the signal channels CH0, CH1, and CH2 with equivalent lengths P1, P2, and P3, differences in response characteristics that may occur due to differences in signal line specifications between one signal channel and another signal channel can be minimized. The structure of the signal channels of FIG. 5 will be described with reference to FIGS. 6A, 6B, and 6C.

FIGS. 6A, 6B, and 6C shows cross-sectional views of signal channels according to embodiments of the present disclosure.

In FIGS. 6A, 6B, and 6C, XZ planes of the signal channels in the respective sections 530a, 530b, and 530c are shown through cross-sectional views. For example, in FIG. 6A shows a cross-sectional view of an XZ plane of an interposer 600a including the signal channels CH0, CH1, and CH2 in the section 530a, FIG. 6B shows a cross-sectional view of an XZ plane of an interposer 600b including the signal channels CH0, CH1, and CH2 in the section 530b, and FIG. 6C shows a cross-sectional view of an XZ plane of an interposer 600c including the signal channels CH0, CH1, and CH2 in the section 530c.

Referring to FIG. 6A, signal lines 620a, 621a, and 622a transmitting signals may be disposed on the layers L1 and L2 in the interposer 600a. Reference lines 611, 612, 613, and 614 may be disposed around the signal lines 620a, 621a, and 622a forming one signal channel group. For example, the reference lines 611 and 612 may be disposed around the signal line 620a in the X-axis direction on the same layer L1, and the signal lines 621a and 622a may be disposed between the reference lines 613 and 614 on the same layer L2. The interposer 600a may include a first reference plate 610 to which a reference voltage is applied above the layers L1 and L2 and a second reference plate 615 to which a reference voltage is applied below the layers L1 and L2.

In the section 530a, the signal channel CH0 may include the first signal line 620a, the signal channel CH1 may include the second signal line 621a, and the signal channel CH2 may include the third signal line 622a.

Referring to FIG. 6B, in the section 530b, the signal channel CH0 may include the second signal line 621b, the signal channel CH1 may include the third signal line 622b, and the signal channel CH2 may include the first signal line 620b.

Referring to FIG. 6C, in the section 530c, the signal channel CH0 may include the third signal line 622c, the signal channel CH1 may include the first signal line 620c, and the signal channel CH2 may include the second signal line 621c.

In an embodiment, each of the signal channels CH0, CH1, and CH2 may include signal lines 620a, 621b, 622c or 620b, 621c, 622a or 620c, 621a, and 622b on the multiple layers (L1 and L2). Thus, according to embodiments of the present disclosure, substantially equivalent response characteristics of signals transmitted through signal channels CH0, CH1, and CH2 may be obtained.

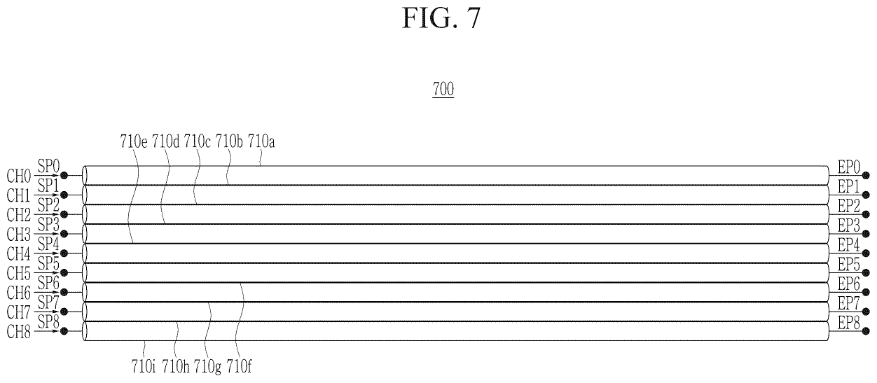

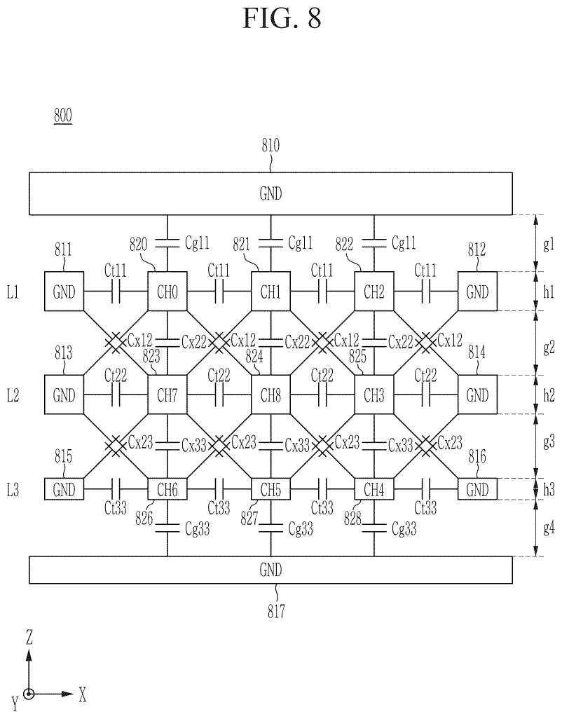

FIG. 7 is a schematic view of signal channels, and FIG. 8 is a cross-sectional view of the signal channels of FIG. 7.

Referring to FIG. 7, a signal channel group may include nine signal channels CH0 to CH8. The signal channels CH0 to CH8 may be respectively single-ended channels, and may electrically connect first points SP0 to SP8 and second points EP0 to EP8, to each other, respectively. One signal channel (CH0, . . . , or CH8) may be implemented by one signal line (710a, . . . , or 710i). In FIG. 7, it is assumed that each of the signal lines CH0 to CH8 between the first points SP0 to SP8 and the second points EP0 to EP8 has a certain specification. The signal lines 710a to 710i may have different specifications. Therefore, differences in response characteristics may occur between signals transmitted through the signal channels CH0 to CH8.

Referring to FIG. 8, signal lines 820 to 828 that transmit signals may be disposed on multiple layers L1, L2, and L3 in an interposer 800. For example, signal lines 820 to 822 respectively corresponding to the channels CH0 to CH2 may be disposed on the layer L1, signal lines 823 to 825 respectively corresponding to the channels CH7, CH8, and CH3 may be disposed on the layer L2, and signal lines 826 to 828 respectively corresponding to the channels CH6, C58, and CH4 may be disposed on the layer L3. Reference lines 811 to 816, to which a reference voltage is applied, may be disposed on the layers L1, L2, and L3 in the interposer 800. The signal lines 820 to 828 and the reference lines 811 to 816 may extend in the Y-axis direction. The reference lines 811 to 816 may be disposed around the signal lines 820 to 828 that form one signal channel group. For example, the reference lines 811 and 812 may be disposed around the signal lines 820 and 822 in the X-axis direction on the same layer L1, the reference lines 813 and 814 may be disposed around the signal lines 823 and 825 in the X-axis direction on the same layer L2, and the reference lines 815 and 816 may be disposed around the signal lines 826 and 828 in the X-axis direction on the same layer L3. For example, on the same layer L1, L2, or L3, the signal lines 820, 821, and 822, or 823, 824, and 825, or 826, 827, and 828 may be disposed between the reference lines 811 and 812, 813 and 814, or 815 and 816. The reference voltage applied to the reference lines 811 to 816 may be the ground voltage GND.

The interposer 800 may include a first reference plate 810 to which a reference voltage is applied above the layers L1, L2, and L3 and a second reference plate 819 to which a reference voltage is applied below the layers L1, L2, and L3. The first reference plate 810 and the second reference plate 817 may be formed of a metal to which the reference voltage, and a space between the first reference plate 810 and the second reference plate 817 may be filled with one or more dielectrics. The reference voltage applied to the first reference plate 810 and the second reference plate 817 may be a ground voltage GND.

The signal line 820 may form capacitive couplings Cg11, Ct11, Cx12, Ct11, Cx22, and Cx12 with the first reference plate 810, the reference lines 811 and 813, and the signal lines 821, 823, and 824. The signal line 823 may form capacitive couplings Cx12, Ct22, Cx23, Cx22, Cx12, Ct22, Cx23, and Cx33 with the reference lines 811, 813, and 815, and the signal lines 820, 821, 824, 826, and 827. The signal line 826 may form capacitive couplings Cg33, Cx23, Ct33, Cx33, Cx23, and Ct33 with the second reference plate 817, the reference lines 813, and 815, and the signal lines 823, 824, and 827.

In embodiments of the present disclosure, nine signal channels CH0 to CH8 in the signal channel group may be implemented by signal lines having a cyclic structure. Signal lines having a cyclic structure within a signal channel group may include signal lines included in a closed plane with the largest area among closed planes formed by three or more signal lines in the signal channel group. For example, with nine signal lines 820 to 828 on the XZ plane as points on the plane, one closed plane may be formed by virtual straight lines including two of the eight points. Since a closed plane formed by eight signal lines 820, . . . , 823, 825, . . . , and 828) has the largest area among the closed planes, the eight signal lines 820, . . . , 823, 825, . . . , and 828 may have a cyclic structure.

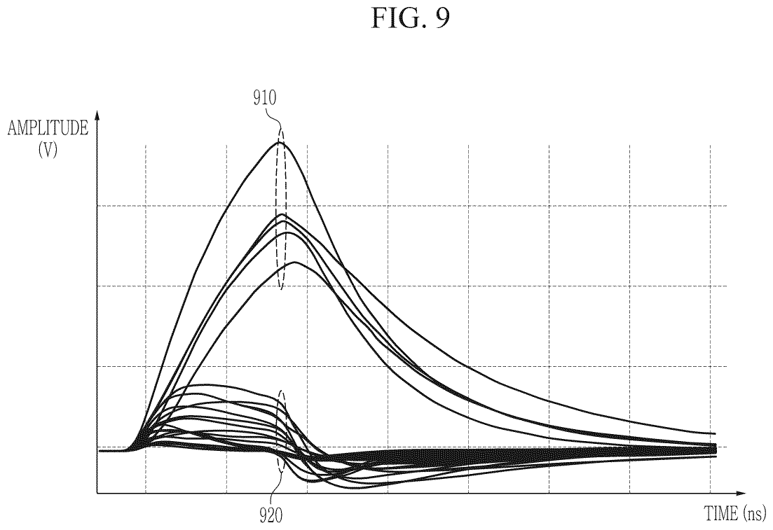

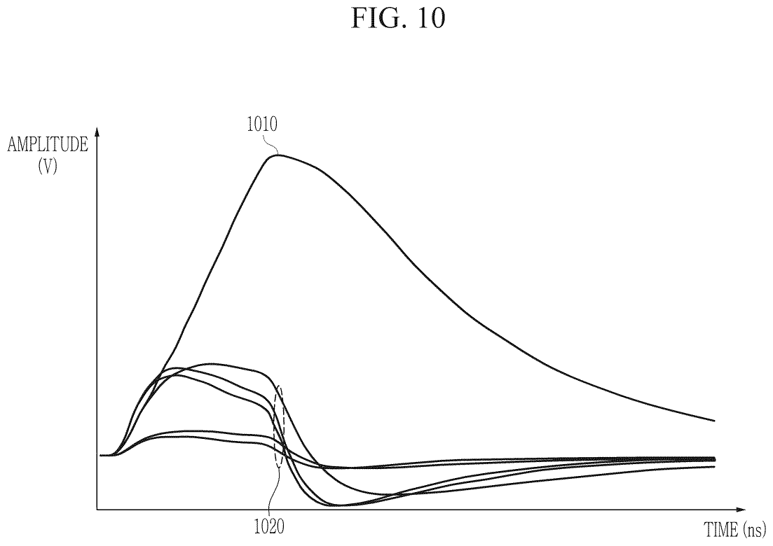

At least one of a thickness hl of the signal lines 820, 821, and 822 and the reference lines 811 and 812 in the Z-axis direction on the layer L1, a thickness h2 of the signal lines 823, 824, and 825 and the reference lines 813 and 814 in the Z-axis direction on the layer L2, and a thickness h3 of the signal lines 826, 827, and 828 and the reference lines 815 and 816 in the Z-axis direction on the layer L3 may be different from the other two thicknesses. For example, since the signal lines 820, . . . , and 828 have different thicknesses, the signal lines 820, . . . , and 828 may have different resistivities. A distance between the lines 820, 821, and 822 and the first reference plate 810 in the Z-axis direction and a distance g4 between the signal lines 826, 827, and 828 and the second reference plate 817 in the Z-axis direction may be different from each other. A distance g2 between the lines 820, 821, and 822 and the lines 823, 824, and 825 in the Z-axis direction and a distance g3 between the lines 823, 824, and 825 and the lines 826, 827, and 828 in the Z-axis direction may be different from each other. For example, the signal lines 820, 821, 822 or 823, 824, 825, or 826, 827, 828 may have different capacitance values depending on the capacitive coupling formed with adjacent reference lines, signal lines, and reference plates. Due to differences in the specifications of these signal lines 820, . . . , and 828, differences in response characteristics may occur between signals transmitted through the signal channels CH0, . . . , and CH8. The difference in response characteristics of the signal channels CH0, . . . , and CH8 will be described with reference to FIG. 9 and FIG. 10.

FIG. 9 and FIG. 10 are graphs of signals measured through the signal channels of FIG. 7.

Referring to FIG. 9, single bit responses 910 and crosstalk responses 920 of the channels CH0, . . . , and CH7, excluding the channel CH8 are illustrated. It may be observed that the single bit responses 910 of the channels CH0, . . . , and CH7 have a large difference from each other. In addition, it may be observed that the crosstalk responses 920 of the channels CH0, . . . , and CH7 also have various deviations. These differences may occur due to differences in specifications between the signal lines 820, . . . , 823, 825, . . . , and 828 corresponding to each of the channels CH0, . . . , and CH7 and differences in capacitance values due to capacitive coupling with surrounding lines and plates.

Referring to FIG. 10, a single bit response 1010 and crosstalk responses 1020 of the channel CH8 are illustrated. The crosstalk responses 1020 represent the response characteristic due to the crosstalk effect occurring between the channel CH8 and other channels CH0, . . . , and CH7. It may be observed through the graph that there is a large difference in response characteristics due to the crosstalk effect that occurs between the channel CH8 and other channels CH0, . . . , and CH7 due to differences in specifications of other channels CH0, . . . , CH7 that affect the channel CH8 and differences in capacitance values caused by the capacitive coupling between the channel CH8 and other channels CH0, . . . , and CH7.

Since the single bit response 910 between the channels CH0, . . . , and CH7 is different, it is difficult to use it as a single channel group, and it is difficult to apply a crosstalk removal scheme based on the similarity of crosstalk responses based on the deviation of crosstalk responses 920 and the deviation of crosstalk responses 1020.

A signal channel, according to the present disclosure, may include signal lines 820, . . . , 823, 825, . . . , and 828 on multiple layers L1 to L3. The signal lines 820, . . . , 823, 825, . . . , and 828 included in one signal channel may have substantially equivalent lengths. Since each of the signal channels CH0, . . . , and CH7 includes at least one of the signal lines 820, . . . , 823, 825, . . . , and 828 with different specifications, it is possible to obtain substantially equivalent response characteristics of the signals transmitted through the signal channels CH0, . . . , and CH7. For example, in one signal channel group, all signal channels CH0, . . . , and CH7 having a cyclic structure include all signal lines 820, . . . , 823, 825, . . . , and 828 in which the signal channels CH0, . . . , and CH7 can be disposed in the same length, a difference in response characteristics that may occur due to differences in signal line specifications between one signal channel and another signal channel can be minimized.

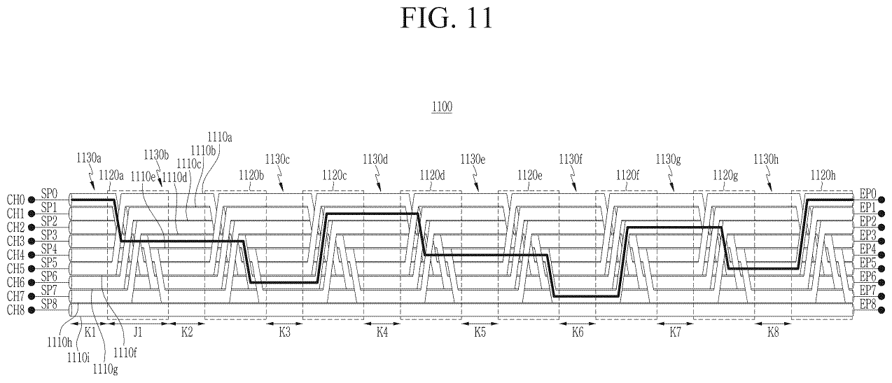

FIG. 11 is a schematic view of signal channels according to embodiments of the present disclosure.

Referring to FIG. 11, a signal channel group may include nine signal channels CH0, . . . , and CH8. The nine signal channels CH0, . . . , and CH8 are examples of the signal channels CH0 to CH8 of FIG. 8. The signal channels CH0, . . . , and CH8 may be respectively single-ended channels, and may electrically connect first points SP0, . . . , and SP8 and second points EP0, . . . , and EP8. In FIG. 11, it is assumed that signal lines 1110a, . . . , and 1110i between the first points SP0, . . . , and SP8 and the second points EP0, . . . , and EP8 has a certain specification. The signal lines 1110a, . . . , and 1110i may have different specifications. A plurality of sections 1130a, . . . , and 1130g may be provided between the first points SP0, . . . , and SP8 and the second points EP0, . . . , and EP8. In embodiments of the present disclosure, the number of the plurality of sections 1130a, . . . , and 1130g may be an integer times the number of signal lines 1110a, . . . , and 1110g having a cyclic structure.

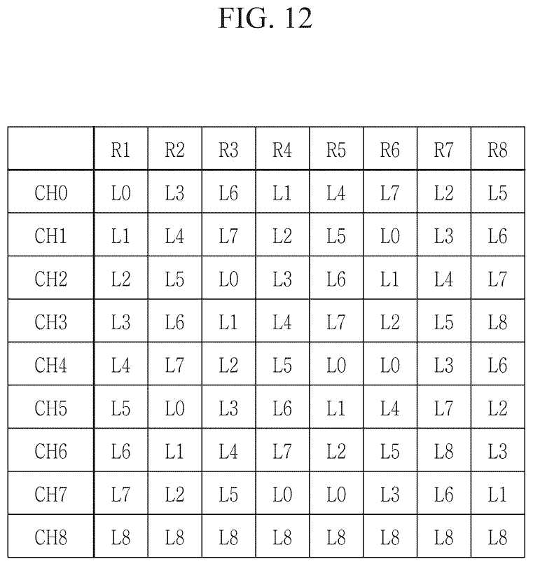

The signal channel group may include eight signal channels CH0, . . . , and CH7 implemented with signal lines having a cyclic structure. One signal channel among the eight signal channels CH0, . . . , and CH7 implemented with the signal lines having the cyclic structure may be implemented with a plurality of signal lines 1110a, . . . , and 1110h. For example, the signal channel CH0 may include a first signal line 1110a in a first section 1130a, a fourth signal line 1110d in a second section 1130b, a seventh signal line 1110g in a third section 1130c, a second signal line 1110b in a fourth section 1130d, a fifth signal line 1110e in a fifth section 1130e, an eighth signal line 1110h in a sixth section 1130f, a third signal line 1110c in a seventh section 1130g, and a sixth signal line 1110f in an eighth section 1130h. This will be described with reference to FIG. 12.

FIG. 12 is a table representing signal lines allocated to signal channels, according to embodiments of the present disclosure.

In FIGS. 12, R1 to R8 denote the plurality of sections 1130a, . . . , and 1130h of FIG. 11, and L0 to L8 denote numbers of the plurality of signal lines 1110a, . . . , and 1110i. It is assumed that numbers of the plurality of signal lines 1110a, . . . , and 1110i are the same as those of the channels CH0, . . . , and CH8 electrically connected to the first points SP0, . . . , and SP8.

Referring to FIG. 12, each of the eight signal channels CH0, . . . , and CH7 implemented with the signal lines having the cyclic structure may include a plurality of signal lines L0 to L7 in each of sections R1 to R8. On the XZ plane, signal lines 1110a, . . . , and 1110h corresponding to the signal lines L0 to L7 may be disposed on the outline of the closed plane along the clockwise direction.

In embodiments of the present disclosure, when the number of signal channels implemented with signal lines having a cyclic structure is N and one channel includes a signal line of a first section and a signal line of a second section, which is adjacent to the first section, the signal line of the second section may be positioned at an A-th along the outline of the closed plane formed by the signal lines having a cyclic structure from the signal line of the first section. Here, A is a positive integer, and may be a value that maximizes the size of (N-A) value among values that are disjoint with N. For example, when N is 8, A may be 3, and when N is 12, A may be 5.

In the example of FIG. 12, N is 8, and therefore it can be observed that a difference between the number of the signal line in the first section and the number of the signal line in the second section adjacent to the first section is 3. For example, the signal line L0 of the first section R1 may be electrically connected to the signal line L3 of the second section R2, which is positioned third in the clockwise direction along the outline of the closed plane.

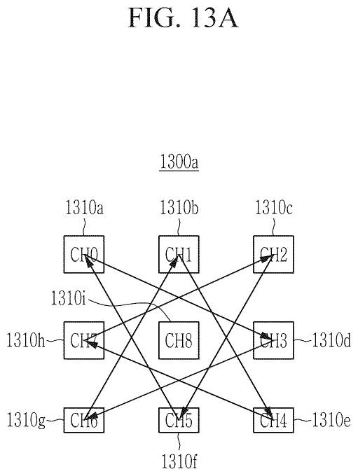

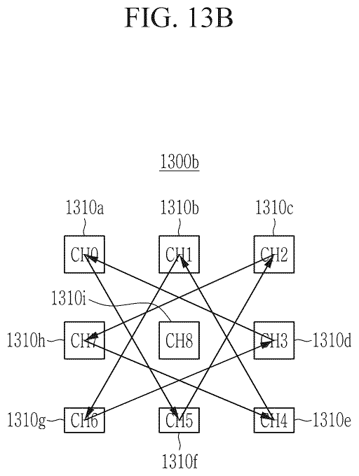

In embodiments of the present disclosure, in the case of signal channels implemented with signal lines having a cyclic structure, a signal line of a second section electrically connected to a signal line of a first section may be an A-th signal line disposed along the outline of the closed plane formed by signal lines having a cyclic structure from the signal line of the first section in the clockwise direction or counterclockwise direction. This will be described with reference to FIGS. 13A and 13B.

FIGS. 13A and 13B show signal lines allocated to signal channels according to embodiments of the present disclosure.

FIGS. 13A and 13B show methods that a signal line electrically connected to one channel is electrically connected to another signal line between two adjacent sections. In FIGS. 13A and 13B, a plurality of signal line 1310a, . . . , and 1310i corresponding to L0 to L8 of FIG. 12.

As shown in FIG. 13A, in the case of signal channels CH0, . . . , and CH7 implemented with signal lines having a cyclic structure, a signal line of the second section electrically connected to a signal line of the first section may be an A-th signal line in the clockwise direction along the outline of the closed plane formed by signal channels implemented with the signal lines having a cyclic structure from the signal line of the first section. For example, the signal line 1300a electrically connected to the channel CH0 may be electrically connected to the signal line 1310d in an adjacent section. The signal line 1310a of the first section may be electrically connected to the signal line 1310d of the second section positioned third in the clockwise direction along the outline of the closed plane formed by the signal channels CH0, . . . , and CH7.

As shown in FIG. 13B, in the case of signal channels CH0, . . . , and CH7 implemented with signal lines having a cyclic structure, a signal line of the second section electrically connected to a signal line of the first section may be an A-th signal line in the counterclockwise direction along the outline of the closed plane formed by signal channels implemented with the signal lines having a cyclic structure from the signal line of the first section. For example, the signal line 1310a electrically connected to the channel CH0 may be electrically connected to the signal line 1310f in an adjacent section. The signal line 1310a of the first section may be electrically connected to the signal line 1310f of the second section positioned third in the counterclockwise direction along the outline of the closed plane formed by the signal channels CH0, . . . , and CH7.

Referring back to FIG. 11, lengths K1, . . . , and K8 of the sections 1130a, . . . , and 1130h may be substantially equivalent to each other. For example, the lengths K1, . . . , and K8) of the eight signal lines included in the first signal channel CH0 may be substantially equivalent. Connection portions 1120a, . . . , and 1120h may be positioned corresponding to the plurality of sections 1130a, . . . , and 1130h, respectively. In each of the connection portions 1120a, . . . , and 1120h, each of the signal lines 1110a, . . . , and 1110i may be electrically connected to different signal lines 1110a, . . . , and 1110i. For example, in the connection portion 1120a, a first signal line 1110a may be electrically connected to a fourth signal line 1110d, a second signal line 1110b may be electrically connected to a fifth signal line 1110e, a third signal line 1110c may be electrically connected to a sixth signal line 1110f, a fourth signal line 1110d may be electrically connected to a seventh signal line 1110g, a fifth signal line 1110e may be electrically connected to an eighth signal line 1110h, a sixth signal line 1110f may be electrically connected to the first signal line 1110a, the seventh signal line 1110g may be electrically connected to the second signal line 1110b, and the eighth signal line 1110h may be electrically connected to the third signal line 1110c. A length J1 of each of the connection portions 1130a, . . . , and 1130h may be very short compared to the lengths K1, . . . , and K8 of the respective sections 1130a, 1130b, and 1130c.

Since each of the signal channels CH0, . . . , and CH8 implemented with signal lines having a cyclic structure includes at least one of the signal lines 1110a, . . . , and 1110i with a specification difference, substantially equivalent response characteristics of signals transmitted through signal channels CH0, . . . , and CH8 can be obtained. When the signal channels CH0, . . . , and CH8 implemented with signal lines having a cyclic structure and included in one signal channel group each includes signal lines 1110a, . . . , and 1110i corresponding to the signal channels CH0, . . . , and CH8 with equivalent lengths K1, . . . , and K8, differences in response characteristics that may occur due to differences in signal line specifications between one signal channel and another signal channel can be minimized.

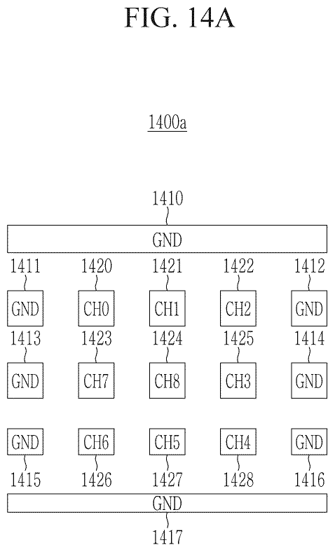

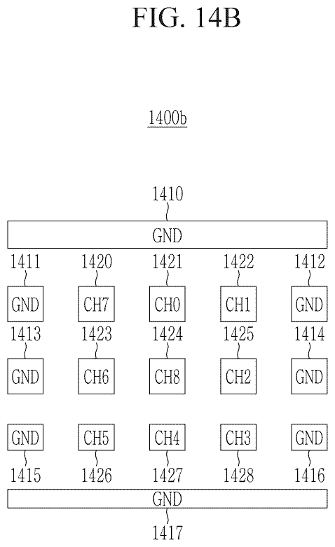

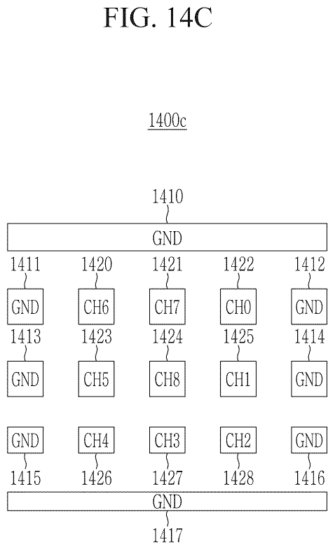

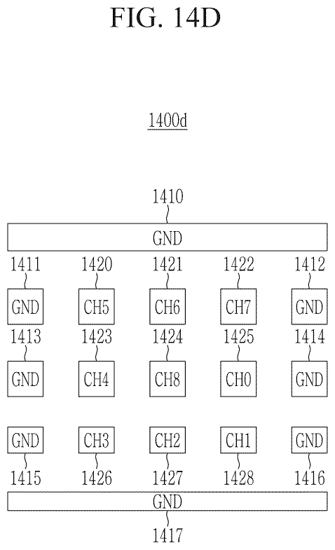

The structure of the signal channels of FIG. 11 will be described with reference to FIGS. 14A, 14B, 14C, and 14D.

FIGS. 14A, 14B, 14C, and 14D are cross-sectional views of signal channels according to embodiments of the present disclosure.

FIGS. 14A, 14B, 14C, and 14D show the XZ plane of the signal channels in one connection portion (e.g., 1120a) of FIG. 11 through cross-sectional views. For example, FIGS. 14A, 14B, 14C, and 14D may be cross-sectional views illustrating the XZ planes according to distances with the first points SP0, . . . , and SP8. For example, in FIG. 14A is a cross-sectional view of a portion 1400a adjacent to the first points SP0, . . . , and SP8, and (D) is a cross-sectional of the most distant portion 1400d in the first points SP0, . . . , and SP8.

One signal line included in one signal channel within one connection portion may be electrically connected to an A-th signal line in the clockwise direction or counterclockwise direction along the outline of a closed plane formed by signal channels implemented with signal lines with a cyclic structure. In one connection portion, one signal channel and the A-th signal line may be electrically connected through A signal lines arranged along the outline of the closed plane. In embodiments of the present disclosure, when A is 2 or more, one signal may be repeatedly electrically connected to a signal line positioned first in the clockwise direction or counterclockwise direction along the outline of a closed plane (i.e., a signal line adjacent to the outline of the closed plane) to connect the signal line of the first section and the signal line of the second section. For example, since A is 3, in the connection portion connecting the signal line of the first section and the signal line of the second section, one signal line may be electrically connected repeatedly three times to the signal line positioned first in the clockwise direction or counterclockwise direction along the outline of the closed plane (i.e., a signal line adjacent along the outline of the closed plane).

As shown in FIG. 14A, the signal channel CH0 may include a signal line 1420 in the portion 1400a adjacent to the first points SP0, . . . , and SP8 in the connection portion.

As shown in FIG. 14B, in a portion next to the portion 1400a, the signal channel CH0 may include a signal line 1421. The signal line 1420 may be electrically connected to the signal line 1421 positioned first in the clockwise direction along the outline of the closed plane.

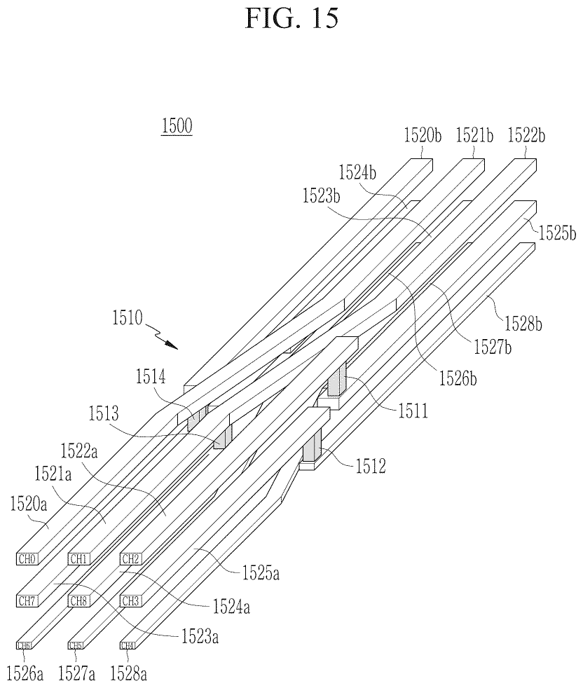

The connections of the signal lines in FIGS. 14A AND 14B will be described with reference to FIG. 15.

FIG. 15 exemplarily illustrate a connection method of signal lines according to embodiments of the present disclosure.

As shown in FIG. 15, a partial connection portion 1510 may be disposed between the portion 1400a and the portion 1400b of FIG. 14, and may electrically connect the plurality of signal lines 1520a, . . . , and 1528a and the plurality of signal lines 1520b, . . . , and 1528b.

In the partial connection portion 1510, the signal line 1520a corresponding to the signal channel CHO may be electrically connected to the first signal line 1521b in the clockwise direction along the outline of the closed plane. In the partial connection portion 1510, the signal line 1521a corresponding to the signal channel CH1 may be electrically connected to the first signal line 1522b in the clockwise direction along the outline of the closed plane. In the partial connection portion 1510, the signal line 1522a corresponding to the signal channel CH2 may be electrically connected to the first signal line 1525b in the clockwise direction along the outline of the closed plane. The signal line 1522a and the signal line 1525b may be electrically connected to each other through a via 1511. In the partial connection portion 1510, the signal line 1525a corresponding to the signal channel CH3 may be electrically connected to the first signal line 1528b in the clockwise direction along the outline of the closed plane. The signal line 1525a and the signal line 1528b may be electrically connected to each other through a via 1512. In the partial connection portion 1510, the signal line 1528a corresponding to the signal channel CH4 may be electrically connected to the first signal line 1527b in the clockwise direction along the outline of the closed plane. In the partial connection portion 1510, the signal line 1527a corresponding to the signal channel CH5 may be electrically connected to the first signal line 1526b in the clockwise direction along the outline of the closed plane. In the partial connection portion 1510, the signal line 1526a corresponding to the signal channel CH6 may be electrically connected to the first signal line 1523b in the clockwise direction along the outline of the closed plane. The signal line 1526a and the signal line 1523b may be electrically connected with each other through a via 1513. In the partial connection portion 1510, the signal line 1523a corresponding to the signal channel CH7 may be electrically connected to the first signal line 1520b in the clockwise direction along the outline of the closed plane. The signal line 1523a and the signal line 1520b may be electrically connected with each other through a via 1514.

As described above, in the partial connection portion 1510, one signal line may be electrically connected to an adjacent signal line in the clockwise direction/or counterclockwise direction. The above-stated connection method is just an example for implementing the connection between signal lines within the connection portion (e.g., 1120a), and in the present disclosure, the connection between signal lines may be implemented in various ways other than the above-stated method.

Next, as shown in FIG. 14C, in a portion next to the portion 1400b, the signal channel CH0 may include a signal line 1422. The signal line 1421 may be electrically connected to the signal line 1422 positioned first in the clockwise direction along the outline of the closed plane.

As shown in FIG. 14D, in a portion 1400d next to the portion 1400c, the signal channel CH0 may include a signal line 1425. The signal line 1422 may be electrically connected to the signal line 1425 positioned first in the clockwise direction along the outline of the closed plane.

As a result, in the connection portion, the signal line 1420 may be electrically connected to the third signal line 1425 in the clockwise direction along the outline of a closed plane formed by signal lines 1420, . . . , 1423, 1425, . . . , and 1428 of a cyclic structure.

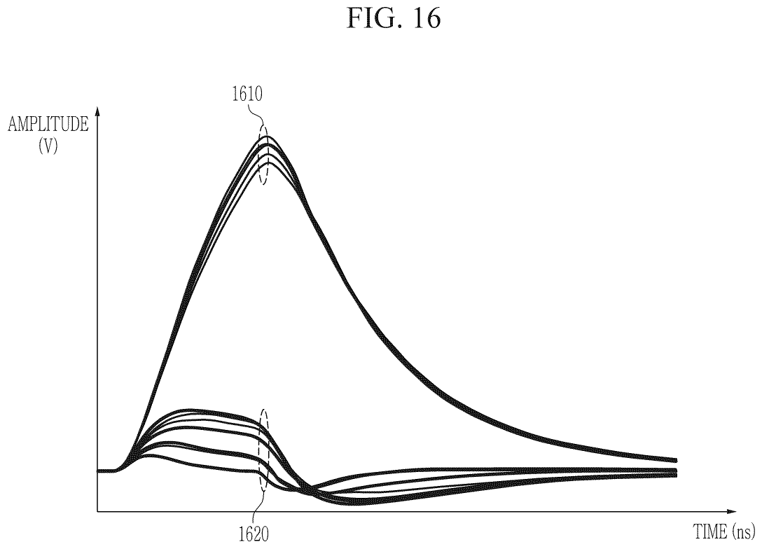

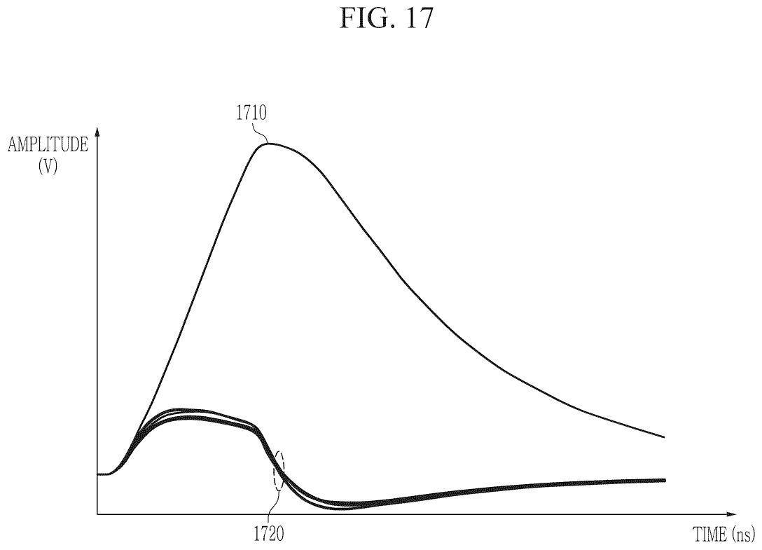

FIG. 16 and FIG. 17 are graphs illustrating signals measured through the signal channels of FIG. 12.

Referring to FIG. 16, single bit responses 1610 and crosstalk responses 1620 of the CH0, . . . , and CH7, excluding the channel CH8 are illustrated. It can be observed that the single bit responses 1610 of the channels CH0, . . . , and CH7 have substantially equivalent characteristics. In addition, it can be observed that the crosstalk responses 1620 of the channels CH0, . . . , and CH7 are classified into several groups with substantially equivalent characteristics. Therefore, the channels CH0, . . . , and CH7 can be used as one channel group, and a crosstalk removal scheme based on the similarity of crosstalk responses can be applied.

Referring to FIG. 17, a single bit response 1710 and crosstalk responses 1720 of the channel CH8 are illustrated. The crosstalk responses 1720 represent the response characteristic due to the crosstalk effect occurring between the channel CH8 and other channels CH0, . . . , and CH7. It can be observed that the crosstalk responses 1720 have substantially equivalent characteristics. Accordingly, a crosstalk removal scheme based on the similarity of crosstalk responses can be applied.

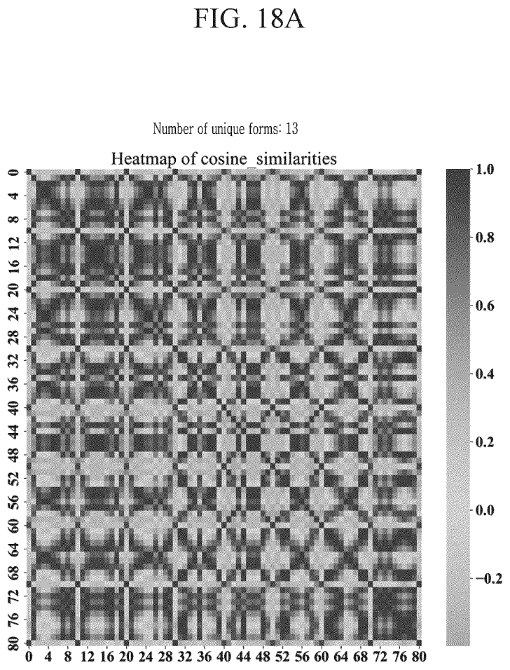

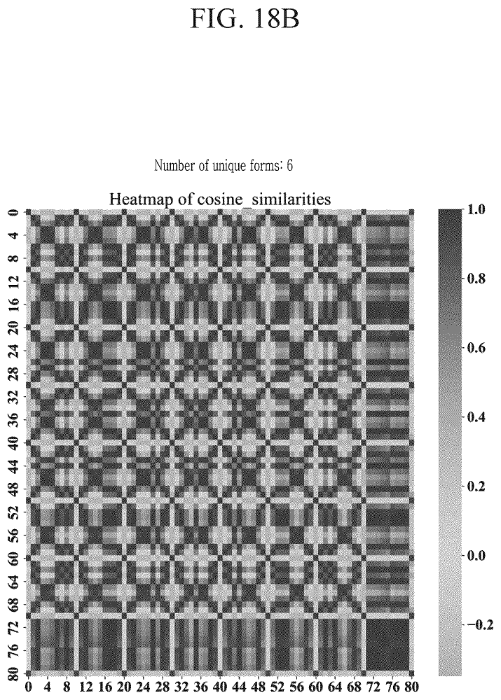

FIGS. 18A and 18B show heat maps that illustrate the similarity of the signal channel response according to embodiments of the present disclosure.

FIG. 18A shows response similarity of a signal channel according to a comparative example described with reference to FIG. 7, and FIG. 18B shows similarity of the signal channels according to the embodiment described with reference to FIG. 11.

As shown in FIGS. 18A and 18B, the horizontal and vertical axes represent response numbers between nine signal channels and nine signal channels, and the shading within the graph represents the similarity between responses. For example, in the graphs FIGS. 18A and 18B, when x=0, the y value represents similarities between a response between the channel CH0 and channel CH0 and a response between one of the nine channels CH0, . . . , and CH8 and one of the nine channels CH0, . . . , and CH8 (i.e., 81 responses). Among the responses between the signal channels, the response between the same two channels may be a single bit response, and the response between two different channels may be a crosstalk response.

Referring to FIG. 18A, the similarity of responses can be divided into 13 groups. For example, the deviation of the similarity of the response varies. Referring to FIG. 18B, the similarity of responses can be classified into 6 groups. For example, the deviation of the similarity of responses is small. Therefore, it is easy to apply the crosstalk removal scheme based on the similarity of the crosstalk response to the signal channel according to the present disclosure.

According to the present disclosure, the signal channel has a crosstalk response characteristic that is classified into several groups similar to the substantially equivalent single bit response characteristic, and thus signal lines with different specifications disposed in multiple layers for large throughput may be used as signal channel groups.

Although embodiments of the present invention have been described in detail above, the present invention is not necessarily limited to the embodiments set forth herein, and various modifications and adjustments made by a person of ordinary skill in the art using the basic concept of the present invention also falls within the scope of the present invention.

What is claimed is:

1. A signal channel, comprising:
a plurality of signal lines disposed on a plurality of layers, wherein each of the plurality of signal lines are spaced apart from each other in a first direction and connect first points and second points to one another,
wherein a plurality of sections are defined between the first points and the second points, and
wherein a first signal line, of the plurality of signal lines, is disposed on a first layer, of the plurality of layers, in a first section, of the plurality of sections, and is electrically connected to a second signal line, of the plurality of signal lines, disposed on a second layer, of the plurality of layers, in a second section, of the plurality of sections.

2. The signal channel of claim 1, wherein:
the plurality of signal lines comprise three or more signal lines that are twisted or braided together.

3. The signal channel of claim 2, wherein:
the three or more signal lines that are twisted or braided together comprise three or more signal lines included in a closed plane having the largest area among closed planes formed by the three or more signal lines that are twisted or braided together.

4. The signal channel of claim 3, wherein:
a number of the three or more signal lines that are twisted or braided together is N, the second signal line is disposed at A-th along the outline of the closed plane from the first signal line,
A is a positive integer, and is a value that maximizes the size of (N-A) value among the values that are disjoint with N.

5. The signal channel of claim 4, wherein:
the second signal line is disposed at A-th along the outline of the closed plane from the first signal line in the clockwise direction or counterclockwise direction.

6. The signal channel of claim 4, wherein:
the first signal line and the second signal line are electrically connected through A signal lines along the outline of the closed plane in a connection portion between the first section and the second section.

7. The signal channel of claim 2, wherein:
a number of the plurality of sections is an integer multiplied by the number of three or more signal lines that are twisted or braided together.

8. The signal channel of claim 2, wherein:
lengths of the plurality of sections are substantially equivalent to each other.

9. The signal channel of claim 1, wherein:
the first signal line is electrically connected to the second signal line through a via connecting the first layer and the second layer in the connection portion between the first section and the second section.

10. The signal channel of claim 1, wherein:
the first signal line and the second signal line have different specifications.

11. The signal channel of claim 1, wherein:
a thickness of the first signal line and the second signal line in the first direction and/or a width of the first signal line and the second signal line in the second direction intersecting the first direction are different from each other.

12. The signal channel of claim 1, further comprising a first reference plate, to which a reference voltage is applied, disposed above the first layer.

13. The signal channel of claim 1, further comprising a second reference plate, to which a reference voltage applied, disposed below the second layer.

14. The signal channel of claim 1, further comprising:
a plurality of first reference lines disposed proximate the first signal line in the first layer and to which a reference voltage is applied and/or a plurality of second reference lines disposed proximate the second signal line in the second layer and to which a reference voltage is applied.

15. A module substrate, comprising:
a substrate main body including a dielectric material and including a plurality of layers spaced apart from each other in a first direction; and
a plurality of signal lines that are disposed on the plurality of layers, wherein the plurality of signal lines electrically connect first points and second points to one another, and wherein the plurality of signal lines are twisted or braided with one another,
wherein a plurality of sections are defined between the first points and the second points, and
wherein a first signal line, of the plurality of signal lines, disposed on a first layer of the plurality of layers in a first section of the plurality of sections is electrically connected to a second signal line, of the plurality of signal lines, disposed on a second layer of the plurality of layers in the second section of the plurality of sections.

16. The module substrate of claim 15, wherein:
the plurality of signal lines that are twisted or braided together comprise three or more signal lines included in a closed plane having the largest area among closed planes formed by the three or more signal lines.

17. The module substrate of claim 16, wherein:
a number of the three or more signal lines that are twisted or braided together is N, the second signal line is disposed at A-th along the outline of the closed plane from the first signal line,
A is a positive integer, and is a value having the largest (N-A) value among the values that are disjoint with N.

18. The module substrate of claim 17, wherein:
the second signal line is disposed at A-th along the outline of the closed plane from the first signal line in the clockwise direction or counterclockwise direction.

19. The module substrate of claim 17, wherein:
the first signal line and the second signal line are electrically connected through A signal lines along the outline of the closed plane in a connection portion between the first section and the second section.

20. A semiconductor system, comprising:
a plurality of stacked memory dies;
a buffer die disposed below the plurality of stacked memory dies;
a memory controller; and
an interposer that includes a plurality of signal lines electrically connecting first points of the memory controller and second points of the buffer die to one another,
wherein a plurality of sections are defined between the first points and the second points, and
wherein a first signal line, of the plurality of first signal lines, disposed on a first layer of the plurality of layers in a first section of the plurality of sections is electrically connected to a second signal line, of the plurality of first signal lines, disposed on a second layer of the plurality of layers in a second section of the plurality of sections.
